(19) United States
(12) Patent Application Publication
(10) Pub. No.: US 2025/0390005 A1
(43) Pub. Date: Dec. 25, 2025

(54) DIRECT CABLE CONNECTION FOR AUTOMOTIVE CAMERAS

(71) Applicant: Amphenol Corporation, Wallingford, CT (US)

(72) Inventors: Joachim Grek, Wallingford, CT (US); Owen R. Barthelmes, Putnam Valley, NY (US); Michael Hoyack, Wallingford, CT (US); Joshua Sproule, Los Angeles, CA (US)

(21) Appl. No.: 19/244,030

(22) Filed: Jun. 20, 2025

Related U.S. Application Data
(60) Provisional application No. 63/662,569, filed on Jun. 21, 2024.

(51) Int. Cl. G03B 17/08; H01R 12/75; H01R 13/52; H01R 13/6592

(52) U.S. Cl. CPC G03B 17/08; H01R 12/75; H01R 13/5205; H01R 13/6592; H01R 2201/26

(57) ABSTRACT

Automotive camera assemblies include a camera back housing defining a cavity for receiving a printed circuit board (PCB) having a PCB connector and a direct connector assembly configured to electrically connect a cable to the PCB connector through the camera back housing. The cable is electrically and mechanically connected to the direct connector assembly at a first end of the direct connector assembly and a second end of the direct connector assembly is configured to electrically and mechanically connect to the PCB connector, and a flex pivot point is defined at an interface between the cable and the direct connector assembly, wherein a portion of the direct connector assembly is adjustable relative to an axis of the cable about the flex pivot point when engaging with the PCB connector.

### CROSS-REFERENCE TO RELATED APPLICATIONS

This application claims the benefit of U.S. Provisional Patent Application No. 63/662,569, filed Jun. 21, 2024, the disclosure of which is incorporated herein by reference in its entirety.

### BACKGROUND

The subject matter disclosed herein generally relates to automotive cameras and, more particularly, to housings and connectors for automotive cameras.

Automotive cameras have become increasingly prevalent in modern vehicles, driven by the demand for advanced driver assistance systems (ADAS) and autonomous driving features. These cameras are integral to enabling functionalities such as lane departure warnings, adaptive cruise control, parking assistance, and object detection. As vehicles incorporate more cameras, the need for compact, reliable, and high-performance camera designs has grown significantly.

### SUMMARY

According to some embodiments, automotive camera assemblies are provided. The automotive camera assemblies include a camera back housing defining a cavity for receiving a printed circuit board (PCB) having a PCB connector and a direct connector assembly configured to electrically connect a cable to the PCB connector through the camera back housing. The cable is electrically and mechanically connected to the direct connector assembly at a first end of the direct connector assembly and a second end of the direct connector assembly is configured to electrically and mechanically connect to the PCB connector, and a flex pivot point is defined at an interface between the cable and the direct connector assembly, wherein a portion of the direct connector assembly is adjustable relative to an axis of the cable about the flex pivot point when engaging with the PCB connector.

In addition to one or more of the features described herein, or as an alternative, further embodiments of the automotive camera assemblies may include that the direct connector assembly includes a connector sub-assembly configured to electrically and mechanically connect to an end of the cable, a grounding crimp sleeve configured to compress and secure a portion of the connector sub-assembly with a portion of the cable, a snap body configured to be arranged about an external surface of the cable and configured to fixedly attach to the camera back housing, and a seal element configured to sealing enclose the snap body and a portion of the cable within the camera back housing.

In addition to one or more of the features described herein, or as an alternative, further embodiments of the automotive camera assemblies may include a cable, wherein the cable comprises a cable inner conductor, a cable dielectric, a shielding element, and a cable jacket.

In addition to one or more of the features described herein, or as an alternative, further embodiments of the automotive camera assemblies may include that the seal element sealing engages with an exterior surface of the cable jacket.

In addition to one or more of the features described herein, or as an alternative, further embodiments of the automotive camera assemblies may include that the connector sub-assembly is connected to an end of the cable, wherein the cable inner conductor, the cable dielectric, and the shielding element extend past an end of the cable jacket, and a flex pivot point is defined proximate the end of the cable jacket.

In addition to one or more of the features described herein, or as an alternative, further embodiments of the automotive camera assemblies may include that the connector sub-assembly includes a connector contact, a connector insulator, and a connector body.

In addition to one or more of the features described herein, or as an alternative, further embodiments of the automotive camera assemblies may include a cable comprising a cable inner conductor, a cable dielectric, a shielding element, and a cable jacket. The connector contact electrically connects to the cable inner conductor, the connector body electrically connects with the shielding element, the cable dielectric is arranged between the cable inner conductor and the shielding element, and the connector insulator is arranged between the connector body and the connector contact.

In addition to one or more of the features described herein, or as an alternative, further embodiments of the automotive camera assemblies may include that the snap body includes a centering element configured to receive the cable, a support rim arranged outward from the centering element, and a plurality of engagement tines extending from the centering element and the support rim, wherein the plurality of engagement tines are configured to fixedly connect to the camera back housing.

In addition to one or more of the features described herein, or as an alternative, further embodiments of the automotive camera assemblies may include that the plurality of engagement tines define tine gaps configured to receive respective grounding tines of the grounding crimp sleeve.

In addition to one or more of the features described herein, or as an alternative, further embodiments of the automotive camera assemblies may include a ground spring arranged to fixedly mount to an interior surface of the camera back housing and support the connector sub-assembly.

In addition to one or more of the features described herein, or as an alternative, further embodiments of the automotive camera assemblies may include that the seal element is a first seal element and the automotive camera assembly further includes a second seal element configured to provide sealing engagement between the snap body and a surface of the camera back housing and a third seal element configured to provide sealing engagement between the snap body and an exterior surface of the cable.

In addition to one or more of the features described herein, or as an alternative, further embodiments of the automotive camera assemblies may include a camera front housing configured to be fixedly attached to the camera back housing.

In addition to one or more of the features described herein, or as an alternative, further embodiments of the automotive camera assemblies may include an optical lens mounted to the camera front housing.

In addition to one or more of the features described herein, or as an alternative, further embodiments of the automotive camera assemblies may include a PCB mounted between the camera front housing and the camera back housing, the PCB comprising a PCB connector and a charge-coupled device (CCD) imaging sensor.

In addition to one or more of the features described herein, or as an alternative, further embodiments of the automotive camera assemblies may include that the camera back housing includes a housing body defining an internal cavity for receiving the PCB and a housing post extending from an external surface of the housing body and defining a through hole, wherein the housing post is configured to receive the snap body through the through hole.

In addition to one or more of the features described herein, or as an alternative, further embodiments of the automotive camera assemblies may include that the housing post defines an annular seat configured to receive a portion of the snap body.

In addition to one or more of the features described herein, or as an alternative, further embodiments of the automotive camera assemblies may include that the direct connector assembly includes a connector body configured to electrically and mechanically connect to an end of the cable, a connector snap ring configured to be arranged about an external surface of the connector body, and a seal element configured to sealing enclose the direct connector assembly and a portion of the cable within the camera back housing. The camera back housing includes a housing post with a post protrusion on an interior surface of the housing post, and wherein the post protrusion is captured between a portion of the connector body and the connector snap ring when assembled together.

In addition to one or more of the features described herein, or as an alternative, further embodiments of the automotive camera assemblies may include a cable, wherein the cable comprises a cable inner conductor, a cable dielectric, a shielding element, and a cable jacket.

In addition to one or more of the features described herein, or as an alternative, further embodiments of the automotive camera assemblies may include that the seal element sealing engages with an exterior surface of the cable jacket.

In addition to one or more of the features described herein, or as an alternative, further embodiments of the automotive camera assemblies may include that the connector body is connected to an end of the cable, wherein the cable inner conductor, the cable dielectric, and the shielding element extend past an end of the cable jacket, and a flex pivot point is defined proximate the end of the cable jacket.

The foregoing features and elements may be combined in various combinations without exclusivity, unless expressly indicated otherwise. These features and elements as well as the operation thereof will become more apparent in light of the following description and the accompanying drawings. It should be understood, however, that the following description and drawings are intended to be illustrative and explanatory in nature and non-limiting.

### BRIEF DESCRIPTION OF THE DRAWINGS

The subject matter is particularly pointed out and distinctly claimed at the conclusion of the specification. The foregoing and other features, and advantages of the present disclosure are apparent from the following detailed description taken in conjunction with the accompanying drawings in which:

FIG. 1 is a schematic illustration of a conventional camera front assembly of an automotive camera assembly;

FIG. 2 is a schematic illustration of a conventional camera back assembly of an automotive camera assembly;

FIG. 3 is a schematic illustration of the camera front assembly of FIG. 1 assembled to the camera back assembly of FIG. 2;

FIG. 4 is a schematic illustration of the degrees of freedom and adjustment of components of the camera assembly of FIG. 3;

FIG. 5 is a schematic illustration of an automotive camera assembly having a direct connector assembly in accordance with an embodiment of the present disclosure;

FIG. 6 is a schematic illustration of a cable and components of a direct connector assembly of the automotive camera assembly of FIG. 5;

FIG. 7 is a cross-sectional illustration of the cable and components of the direct connector assembly of FIG. 6 as assembled;

FIG. 8 is a schematic illustration of a camera back housing of the automotive camera assembly of FIG. 5;

FIG. 9 is a schematic illustration of a snap body of the automotive camera assembly of FIG. 5;

FIG. 10 is a schematic illustration of a grounding crimp sleeve of the automotive camera assembly of FIG. 5;

FIG. 11 is a schematic illustration of a ground spring of the automotive camera assembly of FIG. 5;

FIG. 12 illustrates a degree of tilting provided by the direct connector assembly of FIG. 5;

FIG. 13 is a schematic illustration of an automotive camera assembly having a direct connector assembly in accordance with another embodiment of the present disclosure;

FIG. 14 is a schematic illustration of the components of the automotive camera assembly of FIG. 13, during assembly;

FIG. 15 is an enlarged illustration of parts of the direct connector assembly of the automotive camera assembly of FIG. 13;

FIG. 16 is a schematic illustration of an automotive camera assembly having a direct connector assembly in accordance with another embodiment of the present disclosure;

FIG. 17 is an enlarged illustration of parts of the direct connector assembly of the automotive camera assembly of FIG. 16;

FIG. 18 is a schematic illustration of an automotive camera assembly having a direct connector assembly in accordance with another embodiment of the present disclosure;

FIG. 19 is a schematic illustration of the components of the automotive camera assembly of FIG. 18, during assembly; and

FIG. 20 is an enlarged illustration of parts of the direct connector assembly of the automotive camera assembly of FIG. 18.

### DETAILED DESCRIPTION

As shown and described herein, various features of the disclosure will be presented. A more thorough description will now be provided with reference to the accompanying figures. The details shown in the figures are not necessarily to scale, but are shown to aid in understanding the features of the subject technology.

Automotive cameras feature a housing that integrates an RF connector interface on the rear side of the camera. This design allows the camera to transmit video signals over coaxial RF transmission lines to other vehicle systems. However, the housing must meet stringent requirements for environmental sealing, radio frequency interference (RFI) shielding, and mechanical durability to ensure reliable operation in harsh automotive environments. The housing is often constructed from aluminum and laser welded to achieve water resistance and prevent degradation of sensitive electronic components, such as Serializer/Deserializer (SerDes) chips, which encode video signals.

Automotive camera housing designs face challenges in meeting the demands of modern automotive manufacturing processes. The integration of RF connectors into the housing complicates assembly workflows. Additionally, the presence of connectors can interfere with automated assembly equipment and prevent critical pressure testing of the laser welds after assembly. These limitations hinder the ability to optimize manufacturing efficiency and ensure the integrity of the camera housing.

Furthermore, the size and profile of camera housings have become limiting factors in vehicle integration. Automotive manufacturers increasingly require smaller camera packages to accommodate the compact spaces available in modern vehicle designs. Reducing the overall height and footprint of the camera housing is essential to meet these packaging constraints while maintaining performance standards.

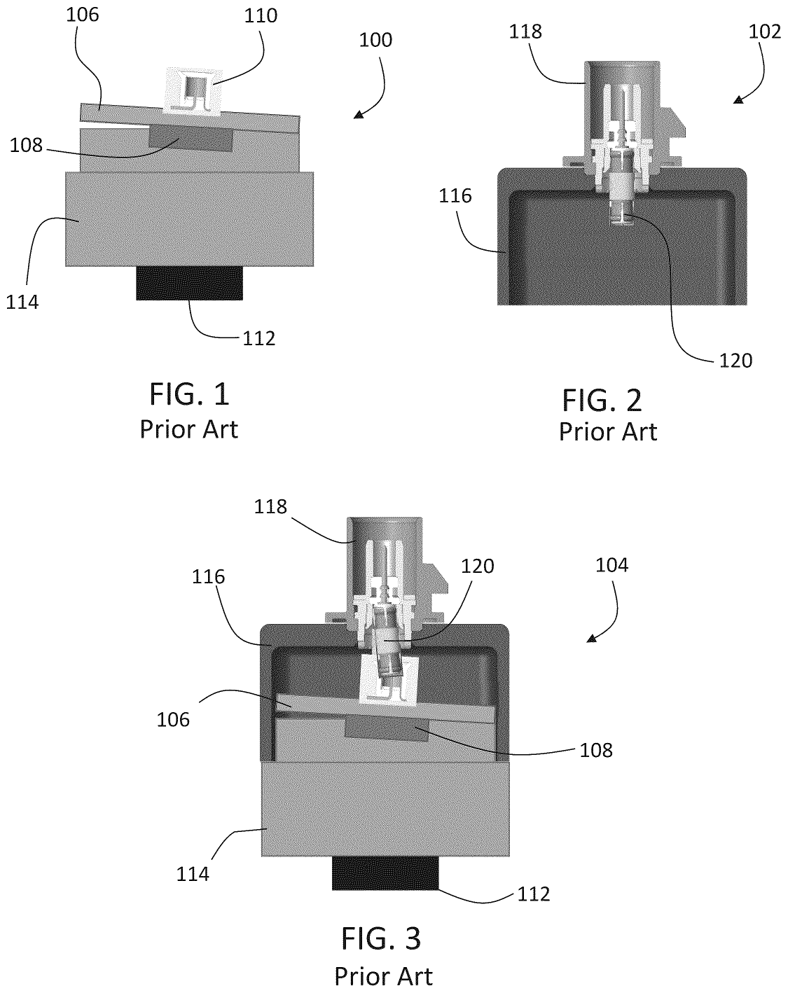

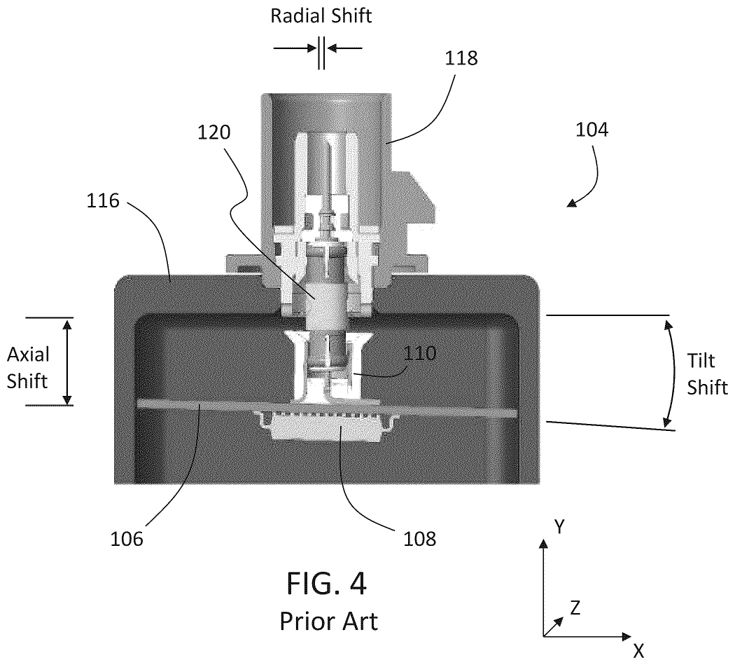

Referring to FIGS. 1-4, the components of a conventional camera manufacturing process are shown. FIG. 1 illustrates a camera front assembly 100, FIG. 2 illustrates a camera back assembly 102, and FIG. 3 illustrates the camera front assembly 100 assembled with the camera back assembly 102 to form a camera assembly 104. FIG. 4 illustrates the degrees of freedom and adjustment of components of the camera assembly 104.

The camera front assembly 100 includes a printed circuit board (PCB) 106, which may include a video Serializer/Deserializer (SerDes) chip (not shown) and a charge-coupled device (CCD) imaging sensor 108, a PCB connector 110, and an optical lens 112 assembled to a camera front housing 114. The CCD imaging sensor 108 is configured to capture images or data from the optical lens 112, which may be processed by the SerDes chip and/or other electronic components of the PCB 106. The PCB connector 110 provides for connection to a cable or cable connector for transmitting image and/or video data to other downstream systems, such as automotive processors or the like.

As shown in FIG. 2, the camera back assembly 102 is a separate structure to which the camera front assembly 100 is assembled to form the camera assembly 104. The camera back assembly 102 includes a camera back housing 116 and a cable connector 118. The cable connector 118 includes an adjustable connector 120 (e.g., bullet connector) that is mounted and arranged within the cable connector 118. The adjustable connector 120 is capable of pivoting or tilting within the cable connector 118 and is configured for electrical and mechanical engagement with the PCB connector 110, as shown in FIG. 3. During assembly, the CCD imaging sensor 108 may require relative adjustment (e.g., tilt, axial, and/or radial adjustment) relative to the optical lens 112. Because the CCD imaging sensor 108 is fixedly mounted on the PCB 106, the entire PCB 106 may be adjusted (e.g., tilt, axial, and/or radial adjustment) to ensure that the optics of the optical lens 112 are focused and aligned with the CCD imaging sensor 108.

Once the PCB 106 and CCD imaging sensor 108 are oriented relative to the optical lens 112, the camera front assembly 100 may be installed into the camera back assembly 102. During the installation, the adjustable connector 120 is inserted into and electrically engaged with the PCB connector 110. Because the PCB 106 may be tilted, axial adjusted, and/or radial adjusted to ensure optical performance, the adjustable connector 120 is also free to tilt, pivot, or otherwise accommodate the adjustment of the PCB 106, while ensuring necessary electrical connection and fidelity.

During installation of the PCB 106 to the camera front housing 114, for optical alignment of the CCD imaging sensor 108 with the optical lens 112, the PCB 106 may be adjusted about the X-Y-Z axes to focus the optical lens 112 to the CCD imaging sensor 108. Once the optimal position is achieved, the PCB 106 is fixed permanently in place to the camera front housing 114. The camera back housing 116 is integrated with an RF connector interface in the form of the cable connector 118 and adjustable connector 120. This adjustable connector 120, in this configuration, is a “bullet” RF interface that is designed to adapt to positional variations in the PCB connector 110 during assembly. The PCB connector 110 is integral with the PCB 106 and thus will be tiled or shifted when the CCD imaging sensor 108 is aligned with the optical lens 112. As shown in FIG. 4, the components of the camera front assembly 100 (e.g., PCB 106 and PCB connector 110) may be shifted axially, radially, and/or tilted with respect to the camera front housing 116 (axial being along a connection direction of the cable connector 110 with the adjustable connector 120). When the camera front assembly 100 and the camera back assembly 102 are joined together, the adjustable connector 120 may tilt or pivot as it engages with the cable connector 110, to accommodate any offsets or adjustments of the components of the camera front assembly 100. The camera assembly 104 is typically sealed using laser welding, although other methods such as threaded fasteners, adhesives, or ultrasonic welding may also be employed. Laser welding is preferred for its ability to achieve water resistance and ensure the integrity of the housing of the camera assembly 104.

The conventional manufacturing assembly has several limitations. For example, an attached cable, which connects to the cable connector 118, can interfere with automated assembly equipment, complicating the production process. Additionally, the presence of the cable can prevent pressure testing of laser welds after assembly is complete, which is critical for verifying the integrity of the housing. These challenges highlight the need for improved manufacturing workflows that simplify assembly, enable automation, and allow for comprehensive testing of the environmental sealing of the housing.

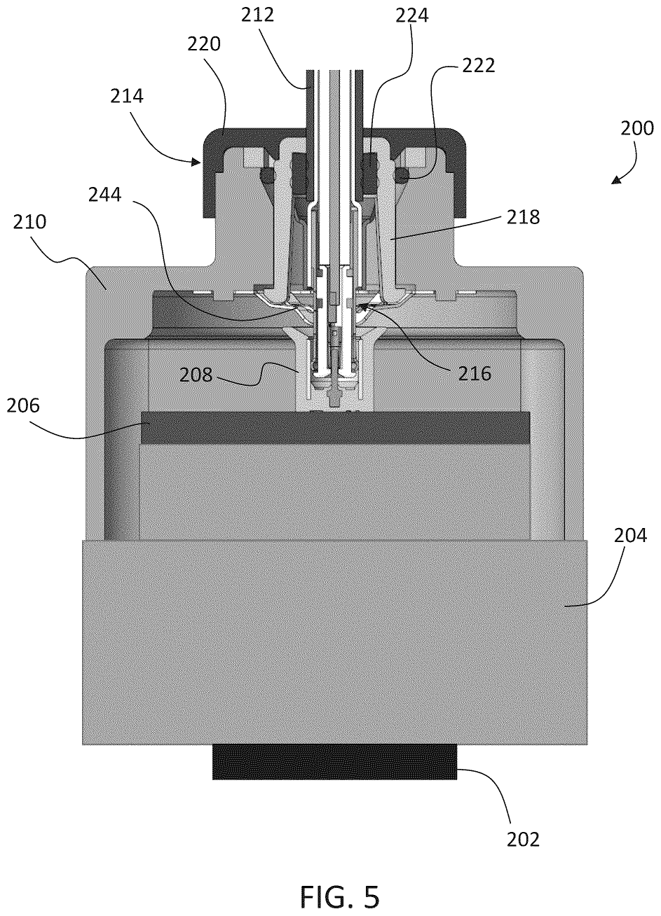

Referring now to FIGS. 5-12, schematic illustrations of an automotive camera assembly 200 in accordance with an embodiment of the present disclosure are shown. The automotive camera assembly 200 includes an optical lens 202 that is mounted to a camera front housing 204 and operably connected or coupled to a PCB 206. The PCB 206 includes a PCB connector 208, similar to that shown and described above. The camera front housing 204 is assembled to a camera back housing 210 and a cable 212 may be directly electrically connected to the PCB connector 208 via a direct connector assembly 214. The direct connector assembly 214 includes a connector sub-assembly 216 that is configured to interface with and electrically connect to the PCB 206 via the PCB connector 208 at one end/side and to the cable 212 at an opposite end/side. The direct connector assembly 214 includes a snap body 218 for mechanically engaging with the camera back housing 210 and a set of sealing elements 220, 222, 224 for fluidly sealing the automotive camera assembly 200 at the connection point between the cable 212 and the PCB connector 208.

The automotive camera assembly 200, and particularly the direct connector assembly 214 provides for improved camera assembly and manufacture by providing a direction coupling or connection between the cable 212 and the PCB connector 208, without the need for the adjustable connector (e.g., adjustable connector 120 shown in FIGS. 1-4). The assembly process begins the same as described above, with the optical lens 202 and PCB 206 arranged, oriented, and aligned within the camera front housing 204. As discussed above, the PCB 206, and thus the PCB connector 208, may be tilted or shifted from a center point during the alignment and calibration of the optical lens 202 with a CCD imaging sensor (not shown). There is no requirement for connection with the cable 212 at this initial assembly step. Rather, the camera front assembly (elements 202, 204, 206, 208) may be installed into the camera back housing 210 prior to connection with the cable 212. After the camera front assembly is installed into the camera back housing 210 and welded or otherwise permanently affixed thereto, the direct connector assembly 214 may be used to electrically and mechanically connect the cable 212 to the PCB connector 208. As described herein, the direct connector assembly 214 provides for adjustments (e.g., tilt, axial, radial) without the need for a separate component (e.g., the adjustable connector 120).

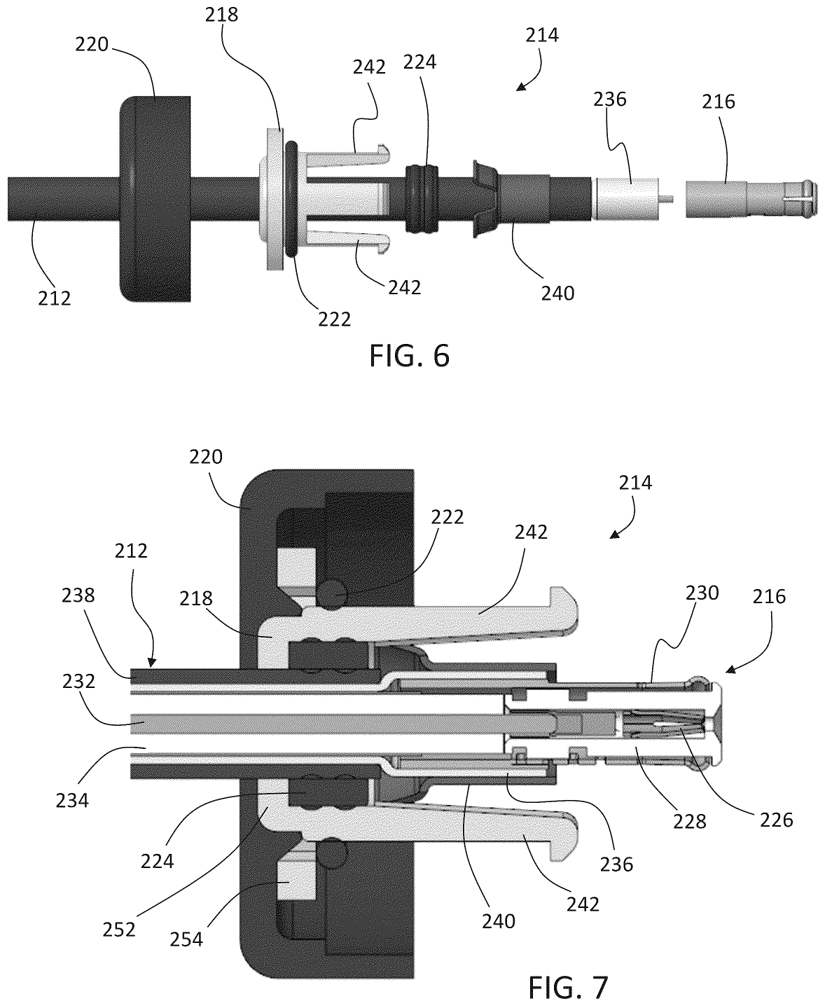

FIG. 6 illustrates the components of the direct connector assembly 214 as arranged on the cable 212 prior to attaching the components to the cable 212. FIG. 7 illustrates the components of the direct connector assembly 214 as installed and attached to the cable 212. The direct connector assembly 214 includes the connector sub-assembly 216 that is configured to electrically connect and couple to an end of the cable 212. The connector sub-assembly 216 includes a connector contact 226, a connector insulator 228, and a connector body 230. The cable 212 includes a cable inner conductor 232, a cable dielectric 234, a shielding element 236, and a cable jacket 238. As shown in FIG. 7, the cable inner conductor 232 is configured to electrically connect and/or connect that connector contact 226 of the connector sub-assembly 216, which can then be electrically connected and coupled to the PCB connector 208 (as shown in FIG. 5). The connection and insertion of the connector sub-assembly 216 at the end of the cable 212 provides for accommodating offsets (e.g., tilt, axial, radial) of the PCB connector 208, eliminating the need for a separate component (e.g., the adjustable connector 120).

As shown in FIGS. 6-7, the direct connector assembly 214 further includes a grounding crimp sleeve 240. The grounding crimp sleeve 240 may be crimped or otherwise physically and electrically arranged in contact with the shielding element 236, as shown in FIG. 7. As such, when assembled, the shielding element 236 is arranged between the grounding crimp sleeve 240 and the connector body 230 of the connector sub-assembly 216. In the assembled state, the sealing elements 220, 224 sealingly engage with the exterior or outer diameter surface of the cable jacket 238. Arranged axially between the first sealing element 220 and the third sealing element 224 is the snap body 218. The snap body 218 fits about the exterior or outer diameter of the cable jacket 238. A second sealing element 222 is provided about an exterior or outer diameter of the snap body 218 and is provided to sealingly engage with a portion of the camera back housing 210, as shown in FIG. 5. The first sealing element 220 also sealing engages with a portion of the camera back housing 210, as shown in FIG. 5. The first sealing element 220 may engage with the camera back housing 210 by interference fit, press fit, snap fit, threaded connection, or the like, as will be appreciated by those of skill in the art. The snap body 218 includes one or more engagement tines 242. The engagement tines 242 are configured to fixedly engage with the camera back housing 210 to secure the end of the cable 212 to the automotive camera assembly 200, as shown in FIG. 5.

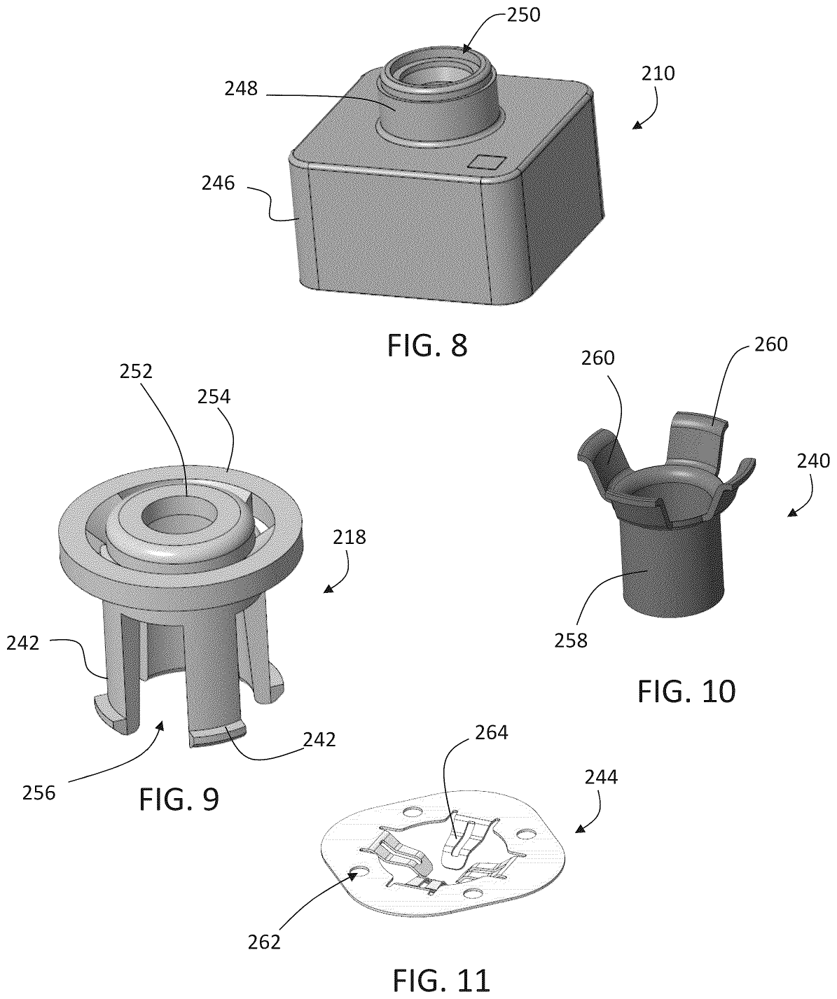

Referring now to FIGS. 8-11, schematic illustrations of components of the automotive camera assembly 200 are shown. FIG. 8 illustrates the camera back housing 210, FIG. 9 illustrates the snap body 218, FIG. 10 illustrates the grounding crimp sleeve 240, and FIG. 11 illustrates a ground spring 244 which is arranged within the camera back housing 210 with the connector sub-assembly 216 configured to pass through the ground spring 244. The ground spring 244 provides a spring force to secure the connector sub-assembly 216 to the camera back housing 210 and to provide shielding between the components of the PCB 206 and external RF interference.

As shown in FIG. 8, the camera back housing 210 includes a housing body 246 and a housing post 248. The housing body 246 is sized to receive the PCB 206 and related components within an internal cavity defined within the housing body 246. In this configuration, the housing body 246 is open at an end or side opposite the housing post 248 and provides access to the internal cavity of the housing body 246. The PCB 206 and related components (e.g., camera front housing 204, PCB connector 208) may be inserted into the internal cavity of the housing body 246, and then may be welded or otherwise affixed to the housing body 246, as described above. The housing post 248 defines an aperture, hole, or opening in the top of the housing body 246 allowing for parts of the direct connector assembly 214 to be inserted therethrough. The housing post 248, in this illustrative configuration, includes an annular channel or seat 250 defined at an end of the housing post 248. The seat 250 is configured to receive a part of the snap body 218 and have the snap body 218 fixed in position relative to the housing body 246.

FIG. 9 illustrates features of the snap body 218. The snap body 218 includes a centering element 252 and a support rim 254. Extending from the centering element 252 and the support rim 254 are the engagement tines 242. The support rim 254 is configured to be seated in the seat 250 of the housing post 248 of the camera back housing 210. The centering element 252 is positioned within the support rim 254 and defines a through hole for receiving and centering the cable 212 and allowing the cable 212 and components thereof to pass through (e.g., as shown in FIG. 7). The engagement tines 242 are separated by tine gaps 256, which are arranged to receive and engage with parts of the grounding crimp sleeve 240. In accordance with some embodiments, the material of the snap body 218 may be plastic or other non-conducting material.

For example, referring to FIG. 10, a schematic illustration of the grounding crimp sleeve 240 is shown. The grounding crimp sleeve 240 includes a crimping body 258 and a set of grounding tines 260 extending from an end of the crimping body 258. The crimping body 258 is configured to receive portions of the cable 212 (e.g., the cable inner conductor 232, the cable dielectric 234, the shielding element 236, and at least a portion of the connector sub-assembly 216 attached to an end of the cable 212, as shown in FIG. 7). The crimping body 258 may be mechanically compressed or crimped about the elements at the end of the cable 212 to secure them together. The grounding tines 260 are configured to fit into the tine gaps 256 of the snap body 218. In accordance with some embodiments, the grounding crimp sleeve 240 may be formed from a conducting material to provide a ground path when assembled.

FIG. 11 is a schematic illustration of the ground spring 244. The ground spring 244 is configured to provide shielding between the components of the PCB 206 and external RF interference. The ground spring 244 includes a set of positioning holes 262 and a set of spring arms 264. The positioning holes 262 may be configured to fit over or engage with protrusions, posts, or the like on the inside surface of the housing body 246 around the housing post 248 to secure the position and orientation of the ground spring 244 within the camera back housing 210. The spring arms 264 are configured to contact and provide electrical connection with the connector body 230 of the connector sub-assembly 216 (as shown in FIG. 5).

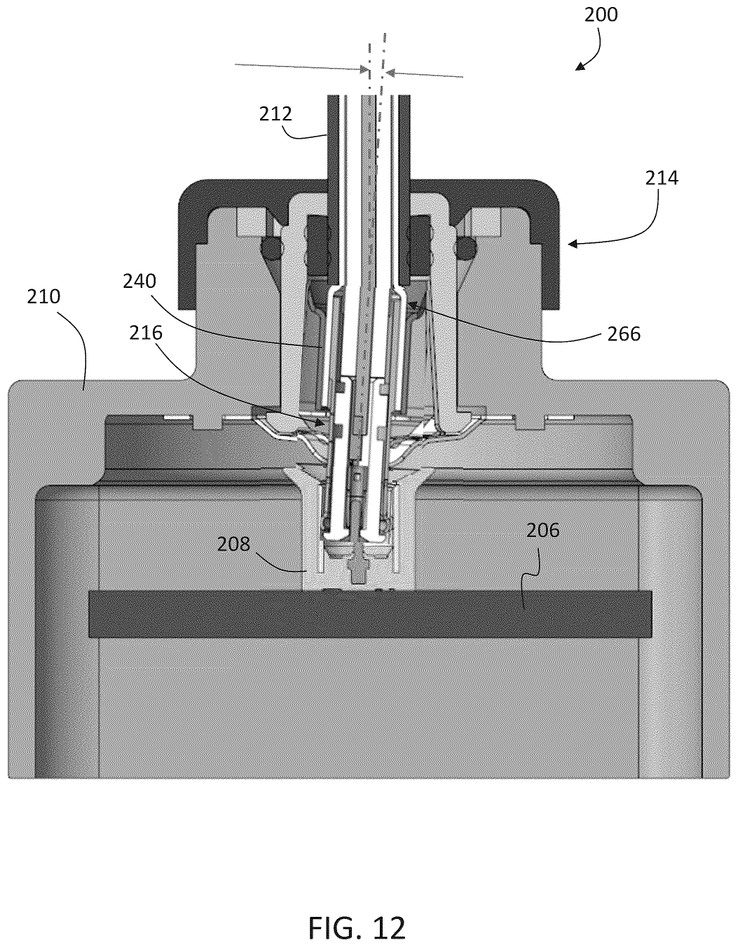

FIG. 12 illustrates the flexibility provided by the direct connector assembly 214 for the automotive camera assembly 200. Instead of relying upon an adjustable connector (e.g., adjustable connector 120 shown in FIGS. 1-4), the flexibility to adjust the interface connection between the cable 212 and the PCB 206 is provided by the flexibility of the cable 212 itself. The cable 212 defines a flex pivot point 266, providing sufficient bending or tilting to compensate for positional variance in the PCB connector 208 after focusing to the optics. As shown in FIG. 12, for example, the connector sub-assembly 216 may be tilted or angled for insertion and connection with the PCB connector 208. In accordance with some embodiments, the flexibility of the cable 212 operates similar to a ball-socket joint, and can provide tilting relative to an axial engagement (e.g., 4-5° angle of tilt).

In accordance with embodiments of the present disclosure, the cables have inherent flexibility by construction. That is, the cable itself enables bending, flexing, tilting, or the like. In accordance with embodiments of the present disclosure, and with reference, for example, to FIGS. 6, 7, 12, the cable 212 is rigidly held to the connector assembly 216 by crimping the outer braid shield at the grounding crimp sleeve 240. The cable 212 is also rigidly held at a cable entry with the sealing elements 220, 224. The first sealing element 220 is arranged about the snap body 218 and the cable 212 and external to the snap body 218, whereas the third sealing element 224 is arranged about the cable 212 and is arranged within or is encompassed by the snap body 218 (see, FIGS. 6-7, 12). The exposed portion of the cable 212 (e.g., an exposed cable segment) between the rigidly held areas (e.g., between the grounding crimp sleeve 240 and the sealing elements 224, 220) is allowed to flex enough to allow a small degree of tilt in the connector assembly 216 to achieve misalignment to the PCB connector 208 at the flex pivot point (region) 266, as shown in FIG. 12.

With reference to FIGS. 5-12, the connector sub-assembly 216 is a coaxial transmission line with the connector body 230, the connector insulator 228, and the connector contact 226 that attaches to the cable 212 on one end and provides for a separable connector interface on the other end for engagement with the PCB connector 208. The cable 212 is prepared so that the cable inner conductor 232 can be attached to the connector contact 226 and the shielding element 236 can be attached to and/or electrically connected to the connector body 230. The grounding crimp sleeve 240 is positioned around the shielding element 236 of the cable 212 and is crimped/compressed to sandwich the shielding element 236 to the connector body 230. The grounding crimp sleeve 240 provides a mechanical and electrical connection to the connector body 230. The snap body 218 is configured to bottom against the grounding crimp sleeve 240, forcing the grounding crimp sleeve 240 into position to ensure the connector sub-assembly 216 mates to the PCB 206. The snap body 218 is pushed into the camera back housing 210 and the engagement tines 242 deflect inward and then snap outward into position to lock the connector sub-assembly 216 into position. The snap body 218 is configured to prevent the cable 212 from dislodging when pulled, even due to the high forces experienced in a vehicle (e.g., 70-120 N) which are common specifications for cable retention. The grounding crimp sleeve 240 is configured to tilt and rotate slightly compared to the snap body 218 thereby allowing for tilt of the connector sub-assembly 216. The sealing elements 220, 222, 224 prevent water ingress. The ground spring 244 provides electrical ground contact between the camera back housing 210 and the connector sub-assembly 216 while permitting slight tilt of the connector sub-assembly 216 due to the flexible spring arms 264.

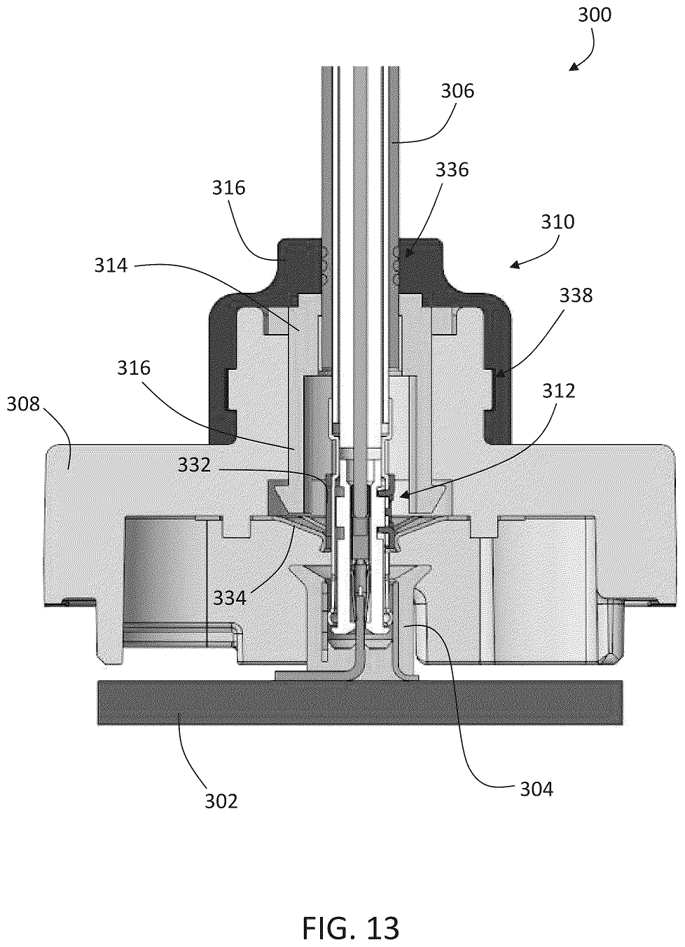

Referring now to FIGS. 13-15, schematic illustrations of an automotive camera assembly 300 in accordance with another embodiment of the present disclosure are shown. The automotive camera assembly 300 may be similar to the automotive camera assembly 200 shown and described above, and thus like features may not be described again, for simplicity and clarity of discussions. FIG. 13 illustrates the automotive camera assembly 300 without the camera front components, other than a PCB 302 and a PCB connector 304 thereof, similar to that shown and described above. Similar to the above-described embodiment, the automotive camera assembly 300 includes a cable 306 that is electrically and mechanically connected to the PCB connector 304 of the PCB 302 within a camera back housing 308.

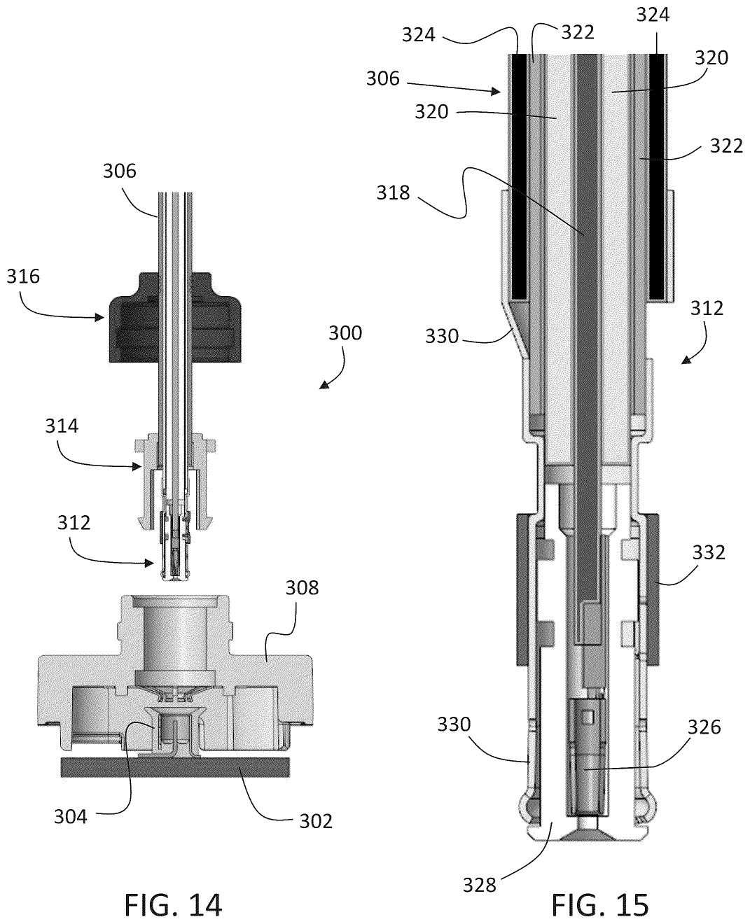

In this configuration, the connection between the cable 306 and the PCB connector 304 is provided by a direct connector assembly 310 having a connector sub-assembly 312. The direct connector assembly 310 includes a snap body 314 and a seal element 316. The snap body 314 includes one or more engagement tines 316 that are configured to mechanically engage and connect to the camera back housing 308, similar to that shown and described above. FIG. 14 illustrates the axial engagement arrangement of components and FIG. 15 illustrates details of the connector sub-assembly 312 installed at an end of the cable 306.

As shown in FIG. 15, the cable 306 includes a cable inner conductor 318, a cable dielectric 320, a shielding element 322, and a cable jacket 324. The end of the cable 306 is configured to receive and electrically connect to the connector sub-assembly 312. The connector sub-assembly 312 includes a connector contact 326, a connector insulator 328, and a connector body 330. As shown in FIG. 15, the cable inner conductor 318 is configured to electrically engage with the connector contact 326, with the connector insulator 328 arranged about the connection therebetween. Outward from the connector insulator 328 is the connector body 330. In this configuration, a grounding crimp sleeve 332 is joined to the connector body 330 to form a single assembly. As shown in FIG. 13, the grounding crimp sleeve 332 may be received by and electrically connected to a ground spring 334.

Some of the primary differences between the automotive camera assembly 300 and the automotive camera assembly 200 include the arrangement of the grounding crimp sleeve 332 and the seal elements(s). In the automotive camera assembly 300, the grounding crimp sleeve 332 does not include the grounding tines 260. Rather, the grounding crimp sleeve 332 is directly crimped or compressed about the connector body 330 of the connector sub-assembly 312. In this configuration, the connector body 330 provides engagement or contact with each of the cable dielectric 320, the shielding element 322, and the cable jacket 324, as shown in FIG. 15. Another difference is the arrangement of the seal elements. In the automotive camera assembly 300, a single seal element 316 is provided. The seal element 316 provides two sealing regions, with a first sealing region 336 defines a seal between the seal element 316 and the cable jacket 324 of the cable 306. A second seal region 338 is defined between the seal element 316 and the camera back housing 308 (e.g., a housing post). However, similar to the automotive camera assembly 200, the automotive camera assembly 300 provides for flexibility and adjustment for the connection between the cable 306 and the PCB connector 304 via tilt and bending provided by the cable 306 itself. That is, the connector sub-assembly 312 provides a direct and adjustable connection between the cable 306 and the PCB connector 304.

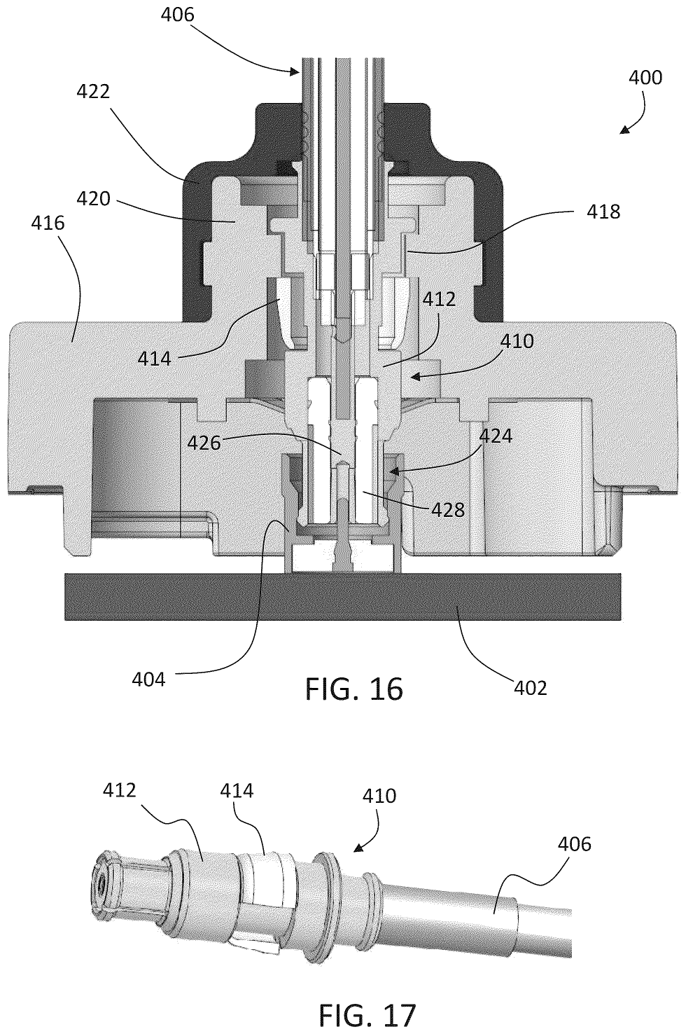

Referring now to FIGS. 16-17, schematic illustrations of an automotive camera assembly 400 in accordance with another embodiment of the present disclosure are shown. The automotive camera assembly 400 may be similar to the automotive camera assemblies shown and described above, and thus like features may not be described again, for simplicity and clarity of discussions. FIG. 16 illustrates the automotive camera assembly 400 without the camera front components, other than a PCB 402 and a PCB connector 404 thereof, similar to that shown and described above. Similar to the above-described embodiments, the automotive camera assembly 400 includes a cable 406 that is electrically and mechanically connected to the PCB connector 404 of the PCB 402 within a camera back housing 408 via a direct connector assembly 410.

In this configuration, the direct connector assembly 410 includes a connector body 412 and a connector snap ring 414. The connector body 412 and the connector snap ring 414 are configured to receive a portion of a camera back housing 416, such as a post protrusion 418 on an inner bore of a housing post 420. In this configuration, the direct connector assembly 410 includes a single seal element 422, providing at least two seal regions (e.g., with the cable 406 and the camera back housing 416). The connector snap ring 414 is configured to fit about a portion of the connector body 412. During installation, the connector snap ring 414 may be compressed and then expanded into engagement such that the post protrusion 418 is captured between the connector snap ring 414 and a part of the connector body 412, as shown in FIG. 16.

The connector body 412 may be formed as an integral or unitary part that encompasses the features of various separate parts of the prior illustrated configurations. For example, the connector body 412 may provide structure and features similar to the connector sub-assembly. For example, the connector body 412 includes a PCB connection end 424 having a connector contact 426 and a connector insulator 428. The connector body 412 extends from the PCB connection end 424 to the cable 406 and connects directed thereto.

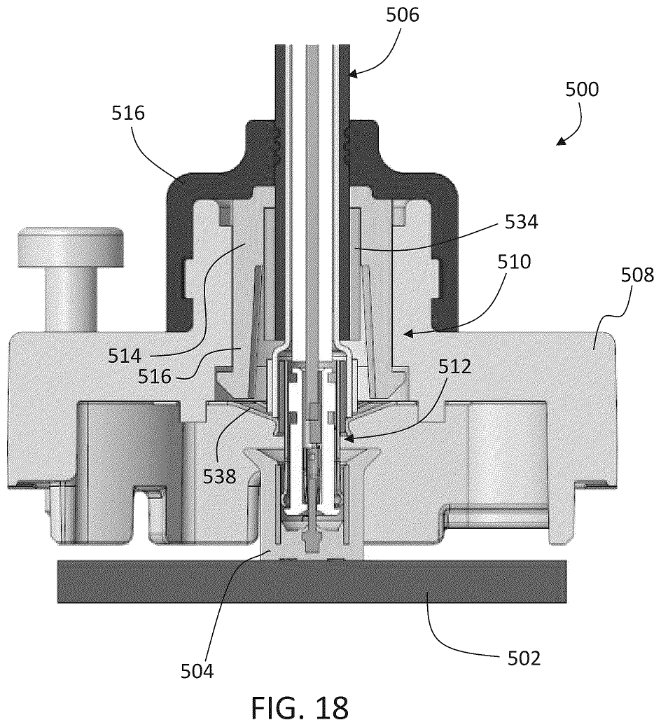

Referring now to FIGS. 18-20, schematic illustrations of an automotive camera assembly 500 in accordance with another embodiment of the present disclosure are shown. The automotive camera assembly 500 may be similar to the automotive camera assemblies shown and described above, and thus like features may not be described again, for simplicity and clarity of discussions. FIG. 18 illustrates the automotive camera assembly 500 without the camera front components, other than a PCB 502 and a PCB connector 504 thereof, similar to that shown and described above. Similar to the above-described embodiments, the automotive camera assembly 500 includes a cable 506 that is electrically and mechanically connected to the PCB connector 504 of the PCB 502 within a camera back housing 508 via a direct connector assembly 510.

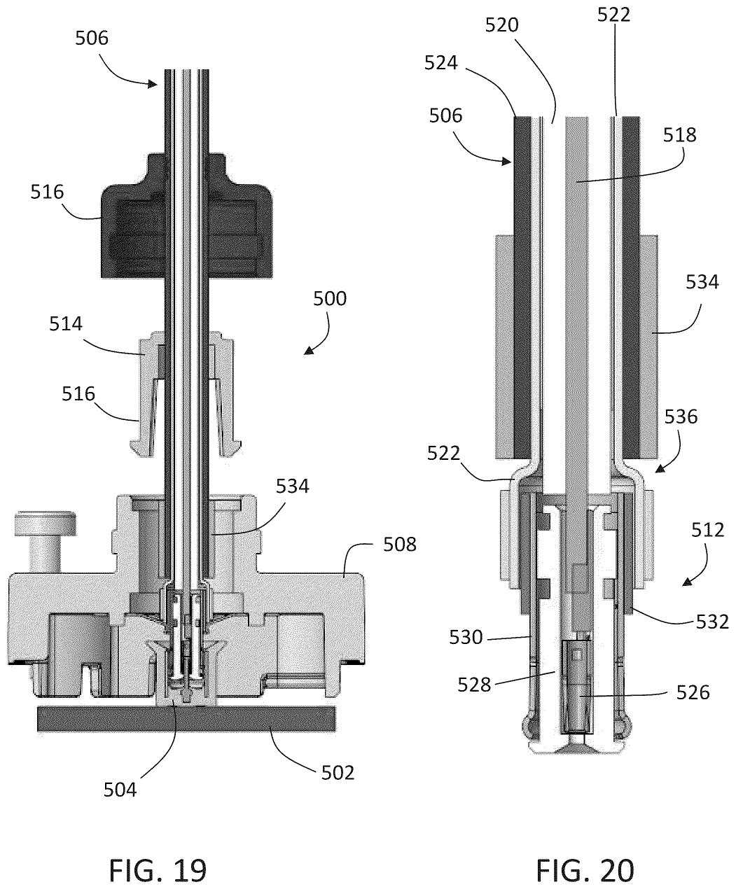

In this configuration, the connection between the cable 506 and the PCB connector 504 is provided by the direct connector assembly 510 having a connector sub-assembly 512. The direct connector assembly 510 includes a snap body 514 and a seal element 516. The snap body 514 includes one or more engagement tines 516 that are configured to mechanically engage and connect to the camera back housing 508, similar to that shown and described above. FIG. 19 illustrates the axial engagement arrangement of components and FIG. 20 illustrates details of the connector sub-assembly 512 installed at an end of the cable 506.

As shown in FIG. 20, the cable 506 includes a cable inner conductor 518, a cable dielectric 520, a shielding element 522, and a cable jacket 524. The end of the cable 506 is configured to receive and electrically connect to the connector sub-assembly 512. The connector sub-assembly 512 includes a connector contact 526, a connector insulator 528, and a connector body 530. As shown in FIG. 20, the cable inner conductor 518 is configured to electrically engage with the connector contact 526, with the connector insulator 528 arranged about the connection therebetween. Outward from the connector insulator 528 is the connector body 530. In this embodiment, there are two crimp sleeves 532, 534. A first crimp sleeve 532 is configured to provide a ground attachment to the connector and a second crimp sleeve 534 is configured for mechanical attachment to the cable jacket 524. The second crimp sleeve 534 bottoms on a locking sleeve for cable pull resistance mechanically. A gap 536 between second crimp sleeve 534 and the first crimp sleeve 534 allows for misalignment compensation to the PCB connector 504 (e.g., tilt, angle, offset). As shown in FIG. 19, the grounding crimp sleeve 532 may be received by and electrically connected to a ground spring 536.

Advantageously, embodiments described herein provide for improved automative camera assemblies. For example, some embodiments of the present disclosure allow for significantly smaller package sizes compared to conventional camera assemblies by eliminating the connector at the camera. By directly attaching the cable to the camera, the size of the assembly can be minimized. Traditional direct cable camera designs are permanently attached to the camera back and thus have typically required additional components and features to allow for manufacturing offsets (e.g., position/orientation of PCB connector). This construction complicates the production steps in the camera assembly. In contrast, embodiments of the present disclosure enable the cable to be directly attached to the camera as the final assembly step, thus enabling automation and testing of laser welds and the like. The push in design of embodiments of the present disclosure allow for fast and positive insertion and captivation to the camera while maintaining environmental, mechanical, RFI shielding, and low loss signal integrity. Embodiments of the present disclosure utilize the flexibility in the cable to allow the RF interface to tilt, thereby accommodating variation in position that is a byproduct of the camera front assembly and focusing of the camera sensor and lens. These and other advantages and benefits will be appreciated by those of skill in the art in view of the teachings herein.

The use of the terms “a”, “an”, “the”, and similar references in the context of description (especially in the context of the following claims) are to be construed to cover both the singular and the plural, unless otherwise indicated herein or specifically contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other. It should be appreciated that relative positional terms such as “forward,” “aft,” “upper,” “lower,” “above,” “below,” and the like are with reference to normal operational attitude and should not be considered otherwise limiting.

While the present disclosure has been described in detail in connection with only a limited number of embodiments, it should be readily understood that the present disclosure is not limited to such disclosed embodiments. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. An automotive camera assembly comprising:
a camera back housing defining a cavity for receiving a printed circuit board (PCB) having a PCB connector; and
a direct connector assembly configured to electrically connect a cable to the PCB connector through the camera back housing, wherein
the cable is electrically and mechanically connected to the direct connector assembly at a first end of the direct connector assembly and a second end of the direct connector assembly is configured to electrically and mechanically connect to the PCB connector, and
a flex pivot point is defined at an interface between the cable and the direct connector assembly, wherein a portion of the direct connector assembly is adjustable relative to an axis of the cable about the flex pivot point when engaging with the PCB connector.

2. The automotive camera assembly of claim 1, wherein the direct connector assembly comprises:
a connector sub-assembly configured to electrically and mechanically connect to an end of the cable;
a grounding crimp sleeve configured to compress and secure a portion of the connector sub-assembly with a portion of the cable;
a snap body configured to be arranged about an external surface of the cable and configured to fixedly attach to the camera back housing; and
a seal element configured to sealing enclose the snap body and a portion of the cable within the camera back housing.

3. The automative camera assembly of claim 2, further comprising:
a cable, wherein the cable comprises a cable inner conductor, a cable dielectric, a shielding element, and a cable jacket.

4. The automotive camera assembly of claim 3, wherein the seal element sealing engages with an exterior surface of the cable jacket.

5. The automotive camera assembly of claim 3, wherein the connector sub-assembly is connected to an end of the cable, wherein the cable inner conductor, the cable dielectric, and the shielding element extend past an end of the cable jacket, and a flex pivot point is defined proximate the end of the cable jacket.

6. The automotive camera assembly of claim 2, wherein the connector sub-assembly comprises:
a connector contact;
a connector insulator; and
a connector body.

7. The automotive camera assembly of claim 6, further comprising a cable comprising a cable inner conductor, a cable dielectric, a shielding element, and a cable jacket, wherein:
the connector contact electrically connects to the cable inner conductor;
the connector body electrically connects with the shielding element;
the cable dielectric is arranged between the cable inner conductor and the shielding element; and
the connector insulator is arranged between the connector body and the connector contact.

8. The automotive camera assembly of claim 2, wherein the snap body comprises:
a centering element configured to receive the cable;
a support rim arranged outward from the centering element; and
a plurality of engagement tines extending from the centering element and the support rim, wherein the plurality of engagement tines are configured to fixedly connect to the camera back housing.

9. The automotive camera assembly of claim 8, wherein the plurality of engagement tines define tine gaps configured to receive respective grounding tines of the grounding crimp sleeve.

10. The automotive camera assembly of claim 2, further comprising a ground spring arranged to fixedly mount to an interior surface of the camera back housing and support the connector sub-assembly.

11. The automotive camera assembly of claim 2, wherein the seal element is a first seal element and wherein the automotive camera assembly further comprises:
a second seal element configured to provide sealing engagement between the snap body and a surface of the camera back housing; and
a third seal element configured to provide sealing engagement between the snap body and an exterior surface of the cable.

12. The automotive camera assembly of claim 2, further comprising:
a camera front housing configured to be fixedly attached to the camera back housing.

13. The automotive camera assembly of claim 12, further comprising an optical lens mounted to the camera front housing.

14. The automotive camera assembly of claim 13, further comprising a PCB mounted between the camera front housing and the camera back housing, the PCB comprising a PCB connector and a charge-coupled device (CCD) imaging sensor.

15. The automotive camera assembly of claim 2, wherein the camera back housing comprises:
a housing body defining an internal cavity for receiving the PCB; and
a housing post extending from an external surface of the housing body and defining a through hole, wherein the housing post is configured to receive the snap body through the through hole.

16. The automotive camera assembly of claim 15, wherein the housing post defines an annular seat configured to receive a portion of the snap body.

17. The automotive camera assembly of claim 1, wherein the direct connector assembly comprises:
a connector body configured to electrically and mechanically connect to an end of the cable;
a connector snap ring configured to be arranged about an external surface of the connector body; and
a seal element configured to sealing enclose the direct connector assembly and a portion of the cable within the camera back housing,
wherein the camera back housing includes a housing post with a post protrusion on an interior surface of the housing post, and
wherein the post protrusion is captured between a portion of the connector body and the connector snap ring when assembled together.

18. The automative camera assembly of claim 17, further comprising:
a cable, wherein the cable comprises a cable inner conductor, a cable dielectric, a shielding element, and a cable jacket.

19. The automotive camera assembly of claim 18, wherein the seal element sealing engages with an exterior surface of the cable jacket.

20. The automotive camera assembly of claim 18, wherein the connector body is connected to an end of the cable, wherein the cable inner conductor, the cable dielectric, and the shielding element extend past an end of the cable jacket, and a flex pivot point is defined proximate the end of the cable jacket.
